(19) United States
(12) Patent Application Publication
(10) Pub. No.: US 2015/0364898 A1
(43) Pub. Date: Dec. 17, 2015

(54) LASER WITH SUB-WAVELENGTH HOLE ARRAY IN METAL FILM

(71) Applicant: PURDUE RESEARCH FOUNDATION, West Lafayette, IN (US)

(72) Inventors: Xiangeng Meng, West Lafayette, IN (US); Jingjing Liu, West Lafayette, IN (US); Alexander V. Kildeshev, West Lafayette, IN (US); Vladimir M. Shalaev, West Lafayette, IN (US)

(73) Assignee: PURDUE RESEARCH FOUNDATION, West Lafayette, IN (US)

(21) Appl. No.: 14/631,601

(22) Filed: Feb. 25, 2015

Related U.S. Application Data
(60) Provisional application No. 61/944,129, filed on Feb. 25, 2014.

(51) Int. Cl. H01S 5/10; H01S 5/323; H01S 3/08; H01S 3/16

(52) U.S. Cl. CPC H01S 5/1042; H01S 3/169; H01S 5/323; H01S 5/1046; H01S 3/08

(57) ABSTRACT

A sub-wavelength scale optical lasing device, for the controlled transfer of a signal in nano- and other small-scale technologies. An array of sub-wavelength size holes is first milled, or otherwise embedded, into a thin metal film. This film is combined with optically active media to compensate for losses of the metal. Optical signals are emitted in the active media, and then transferred to the metal so that surface plasmon polaritons are excited. Lasing occurs as a result of the compensation of plasmonic losses by the available optical gain.

### RELATED APPLICATIONS

The present application claims the benefit of U.S. provisional application Ser. No. 61/944,129, filed Feb. 25, 2014, the contents of which are hereby incorporated by reference in its entirety.

### STATEMENT REGARDING GOVERNMENT FUNDING

This invention was made with government support under N00014-13-1-0649 awarded by the United States Office of Naval Research. The government has certain rights in the invention.

### TECHNICAL FIELD

The present disclosure relates to lasers and specifically to lasers with guided propagation directions.

### BACKGROUND OF THE INVENTION

Surface plasmons, known as collective electron oscillations, occur at the metal/dielectric interface. Surface plasmons are easily excited either optically or electrically. In current technologies, there are approaches to realize nanolasers by amplifying surface plasmons, provided that optical gain media are introduced in the close vicinity to the metal to compensate for plasmonic losses. In comparison to conventional lasers, surface plasmon amplification occurs in the sub-wavelength plasmonic cavity, and thus promises the development of laser devices at truly nanometer scale. However, in contrast to dielectric cavities, the high losses inherent in the metal are impeding the development of such laser devices. The concern of losses is even more obvious in the visible wavelength regime, for instance, the losses at 633 nm are as high as 1.0×10⁻³ cm¹ at the Ag—SiO₂ interface.

Laser, an optical source with high spatial and temporal coherence, is commonly comprised of a resonant cavity and an optical gain medium. The optical gain medium, pumped either electrically or optically, emits photons so that optical feedback is supplied to reach stimulated emission of radiation. The miniaturization of laser devices is highly demanded so as to increase the integration capacity of optical communication networks, digital storage, and detectors. However, in conventional lasers, the cavity is loaded by dielectric media, and thus the physical dimensions and optical mode volume are affected by the diffraction limit. The diffraction limit restrains the footprints of the photonic devices to be on the wavelength scale and prevents them from being integrated with electronic devices. Recently, on-chip plasmonic devices are burgeoning out and provide a solution to this long-standing problem. Such devices utilize surface plasmon polaritons propagating at the metal-dielectric interface with tens of nanometers effective wavelength, and thus allow for manipulation of photons at the sub-wavelength scale. The optical gain medium in the close vicinity to the plasmonic cavity is able to compensate the losses induced by the metal, resulting in surface plasmon amplification. The resultant laser device overcomes the diffraction limit of light, leading to creation of optical sources on the sub-wavelength scale.

Various schemes have been attempted to achieve lasing using plasmonic cavities in the visible wavelength region with unidirectional propagation, but they have not been successful. Core-shell nanoparticle composed of metal as the core and dye-doped dielectric material as the shell have also been employed to achieve nanolasers in the visible wavelength region. In the latter case, the particles are produced using a chemical method. Several fabrication limitations exist. First, dye molecules should be able to be covalently conjugated to the silica precursor through some specific group in the chemical structure of the dye molecule. However, commercial laser dyes are rarely compatible with this method due to the absence of functional groups for covalent bonding. Second, the chemical approach requires stringent fabrication skills to achieve a doping concentration sufficient to compensate plasmon losses. Third, the spectral position of the plasmonic mode in a spherical metal structure is difficult to tune when optimizing the energy transfer from the gain medium to the metal. This is especially troublesome if other gain materials with different emission lines are to be incorporated into a nanolaser design. In addition, the core-shell nanoparticle is incapable of producing unidirectional laser emission.

There have also been attempts using metallic thin films to achieve nanolasers. The optical gain medium, in forms of thin film or single nanostructure, is placed on top of the metallic film. In that case, plasmon losses are still rather high and difficult to be compensated. As a result, nanolasers developed in this way usually operate at cryogenic temperature.

There have been several disclosed attempts to reduce the difficulty to attain plasmonic cavity lasers. One method is to reduce losses of the metal by engineering the crystalline quality of the metal ingredient. Regarding this method, epitaxially grown metal thin films have been developed and employed to realize nanolasers with low threshold. However, thus far, the demonstrations are limited to cryogenic temperatures; and the control of the lasing direction is unsuccessful. Another potential method is to utilize an array of sub-wavelength metal apertures defined as holes or particles as the cavity, forming a coupling of plasmonic resonance modes supported in individual apertures. The coupling provides an intense optical feedback for surface plasmons to attain amplification when optical gain media are supplied near the metal.

### SUMMARY

Disclosed herein is a sub-wavelength scale optical lasing device, for the controlled transfer of a signal in nano- and other small-scale technologies. An array of sub-wavelength size holes is first milled, or otherwise embedded, into a thin metal film. This film is combined with optically active media to compensate for losses of the metal. Optical signals are emitted in the active media, and then transferred to the metal so that surface plasmon polaritons are excited. Lasing occurs as a result of the compensation of plasmonic losses by the available optical gain. Such a device allows for lasing in visible, infrared, and other wavelength/frequency ranges. The metals comprising the film include, but are not limited to, gold, silver, aluminum, copper, and transparent conducting oxides. The device can be tuned, using known equations and relationships, to fit many different technologies. The tuning is based on changing the arrangement of holes, the size, thickness, and shape of holes, as well as the direction of signal emission, and the composition and positioning of the optically active media.

### BRIEF DESCRIPTION OF THE DRAWINGS

The above and other objects, features, and advantages of the present invention will become more apparent when taken in conjunction with the following descriptions and drawings, including the descriptions and drawings in the references identified below. The enclosed Drawings are for purposes of illustration and are not necessary to scale.

FIG. 1 is a schematic of a metal hole array upon excitation with external light, generating coupled plasmon modes between the holes according to one embodiment.

FIG. 2a illustrates a design of optically pumped laser devices with the metal hole array sandwiched between the substrate and the optical gain media.

FIG. 2b illustrates a design of optically pumped laser devices with the metal hole array is located on the top of the optical gain media and exposed to air.

FIG. 3 illustrates a scheme of an electrically pumped laser device with the metal film perforated with hole array serving as the electrode and providing optical feedback for lasing resonance.

FIG. 4 illustrates a scanning electron microscope image of a hole array perforated in a silver film.

FIG. 5a illustrates a transmission spectrum for a metal hole array supported on an ITO-coated glass substrate and exposed to air with the period, diameter, and the thickness as 565 nm, 175 nm, and 100 nm respectively.

FIG. 5b illustrates a transmission spectrum for a metal hole array is supported on an ITO-coated glass substrate and covered by a layer of PVA with the period, diameter, and the thickness as 565 nm, 175 nm, and 100 nm respectively.

FIG. 6 illustrates an emission spectra recorded below and above the pump threshold using a metal hole array of FIG. 4, as the laser cavity and a layer of PVA doped with Rhodamine 101 (R101) as the optical gain medium.

FIG. 7 illustrates an example of a hexagonal arrangement of the metal hole array.

### DETAILED DESCRIPTION

In conventional lasers, the direction of laser emission is controlled by reflective mirrors which provide optical feedback for light amplification. In contrast, the optical feedback in plasmonic lasers is provided by the intrinsic plasmonic resonance, and the emission direction is controlled by the critical angle of surface plasmonic coupling. In addition, the existence of high losses of metal is a large concern in the development of lasers, especially in the visible wavelength region. The invention described herein makes use of coupling effects among plasmonic modes supported in individual holes to provide an intense feedback for light amplification, leading to the creation of lasers with low threshold, high efficiency, and unidirectional propagation direction.

The method described in this application also advantageously supplies optical gain media near the metal hole array through a physical approach, and thus is free of the fabrication difficulty inherent in the chemical approach. The lasing frequency is readily controlled by the period of the hole array and the gain profile of the gain medium.

The hole array is designed via adjusting the structure dimensions in full wave simulations. The diameter and thickness of the holes influence the spectral linewidth of the coupled mode. The optical losses of the cavity are determined by the metal component.

The metal hole array is a periodic array of holes perforated in a metallic thin film. The shape of the holes should be regular. The holes can be circles, ellipses, squares, and any other shape. The spatial arrangement of the hole array can be square, rectangular, hexagonal, and any other pattern. The period of holes in each dimension can be identical or non-identical.

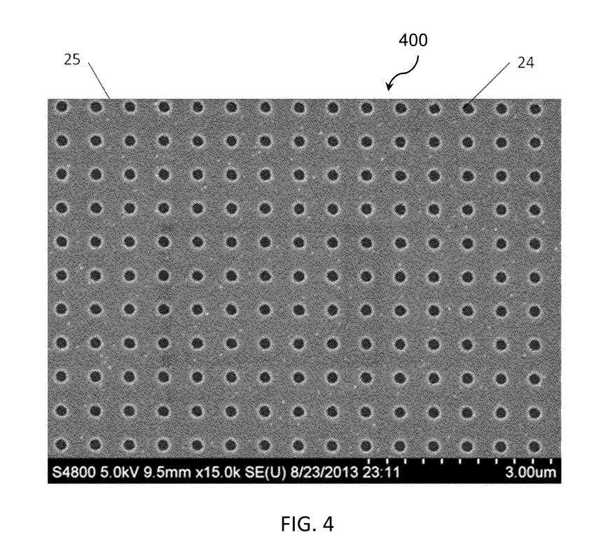

In one embodiment of the metal hole array (see FIG. 4), the holes have circular shapes with the size of the hole at the sub-wavelength scale; and the period along the x-direction is the same to that along the y-direction. These holes contribute to plasmonic resonances equally. The coupling between the resonances of individual holes forms a coupled surface plasmonic wave existing at the interface between metal and optical gain medium. The generation of the surface plasmonic wave provides a constructive optical feedback for light propagating near the interface.

Aspects herein advantageously make use of coupling effects among plasmonic modes supported in individual holes. The feedback created by the coupling has a higher quality factor than that of the individual hole. The spectral position of the lasing wavelength is affected by the spectral profile of the gain medium. As a result, the lasing wavelength emerges at the overlapping region between the gain spectrum and the wavelength of the coupled plasmonic mode. And the spectral profile of the coupled mode appears as a function of the incident angle, providing an option to control the propagation direction of the laser emission.

An array of sub-wavelength metal holes, i.e. a periodic arrangement of holes perforated in the metal film, is a promising way to realize lasing, solar energy harvesting, and sensing in the area of plasmonics. The unique property exhibited by a sub-wavelength metal hole array is well-known as extraordinary optical transmission—optical transmission of light through these holes is greatly enhanced. This phenomenon is correlated with the interactions between surface plasmonic waves and transmission waves through the holes. The corresponding transmission spectrum exhibits an alternating maximum and minimum of transmission signals. These transmission features are described either with:

a surface plasmon polariton-Bloch (SPP-Bloch) wave:

$$Re [ \frac{ω}{c} \sqrt{\frac{{ɛ}_{m} {ɛ}_{d}}{{ɛ}_{m} + {ɛ}_{d}}} ] = \vert {k}_{0} sin θ + i {G}_{x} + j {G}_{y} \vert , \qquad ( 1 )$$

or the Wood anomaly:

$$\frac{ω}{c} \sqrt{{ɛ}_{d}} = \vert {k}_{0} sin θ + i {G}_{x} + j {G}_{y} \vert , \qquad ( 2 )$$

where ω, c, and k₀ are the angular frequency, velocity, and wave vectors of free-space light, respectively, ∈ₘ and ∈_{d} are the permittivity of the metal and dielectric, respectively; Gₓ and G_{y} denote additional wave vectors caused by the grating (Gₓ=G_{y}=2π/Λ); and the integer index pairs (i, j) denote specific SPP modes.

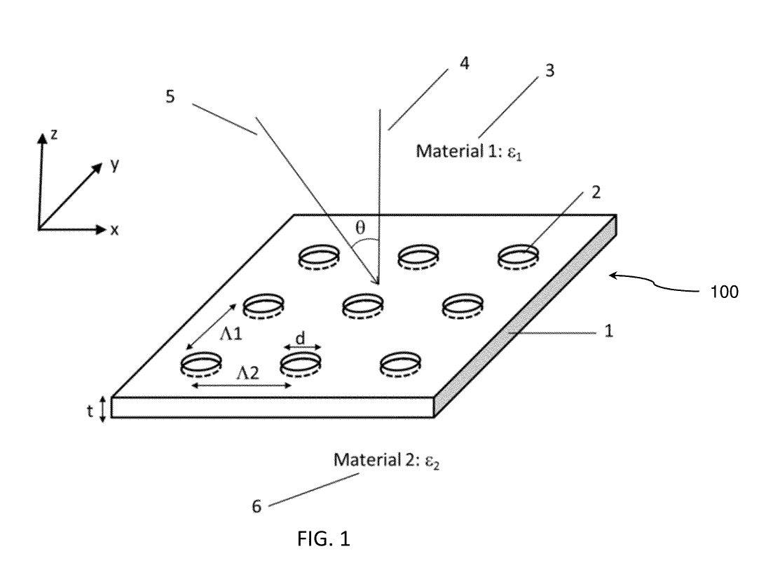

FIG. 1 is a schematic illustration of a metal hole array 100 upon excitation with external light. The hole array 100, comprising holes 2 formed in metal film 1, is distributed in the x-y plane. The surface interface normal 4 is along the z direction. The incident beam 5 exists in the x-z plane. As guided by simulations and the references herein, apparent coupling of the local electric field occurs between the holes 2 at the central frequency of SPP-Bloch wave or Wood anomaly, where an intense optical feedback exists for surface plasmon amplification. As indicated in Eqs. (1) and (2), the central frequency, ω, of the resonance in the metal hole array 100 is determined by several factors: permittivity of the dielectric ∈_{d}, the incident angle κ, and the period of the holes 2, Gx, Gy. The SPP-Bloch wave and/or Wood anomaly may occur at both interfaces of the metal 1, and the corresponding frequency, derived from Eqs. (1) and (2), changes with the neighbor dielectric media (a material 3 covering the film 1 and a material 6 supporting the film 1). The central frequency ω is also different for the x- and y-direction in the case where Gx is different from Gy.

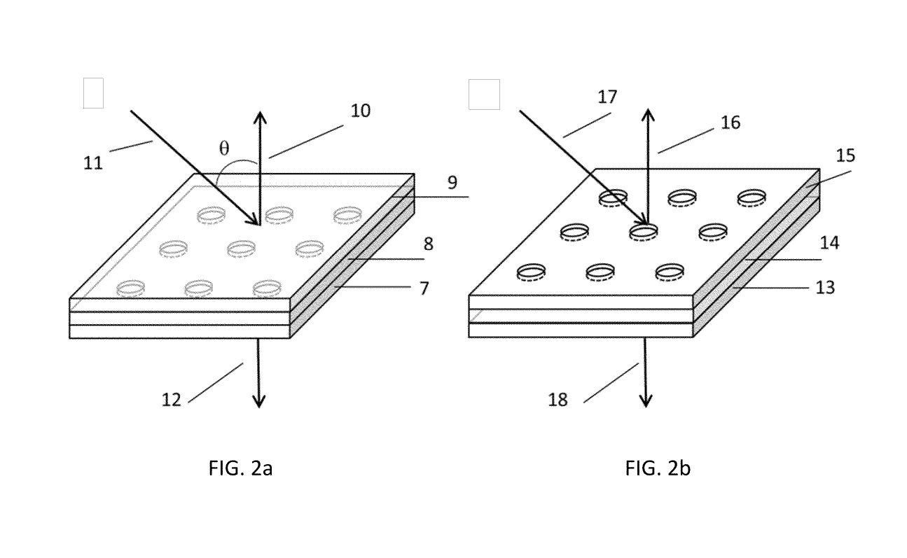

Disclosed herein are at least two embodiments of optically pumped laser devices. One embodiment comprises a metal hole array 8, similar to array 100, sandwiched between an optical gain media 9 and a substrate 7, as shown in FIG. 2a. The substrate 7 preferably comprises a transparent dielectric media such as glass, single crystals, or polymer. In FIG. 2a, reflected lasing emission 10, pump beam 11, and transmitted lasing emission 12 are shown for reference.

FIG. 2b shows a further embodiment which comprises an optical gain media 14, similar to optical gain media 9, sandwiched between a metal hole array 15 (similar to array 8 and 100) and a substrate 13 (similar to substrate 7) while leaving the hole array 15 exposed to air. In FIG. 2a, reflected lasing emission 16, pump beam 17, and transmitted lasing emission 18 are shown for reference.

In the first embodiment (FIG. 2a), the holes are allowed to be filled with the optical gain media 9, so couplings of plasmonic resonance at both metal-substrate and metal-gain interfaces contribute to lasing. The term “performance” herein and below indicates figures of merit for a laser device, such as pump threshold, lasing efficiency, and the like. In the second embodiment (FIG. 2b), the top surface of the metal hole array 15 is exposed to air, while the bottom surface is adjacent to the optical gain media 14, so the mode coupling that occurs at the interface between metal and optical gain media primarily provides optical feedback.

Based on the unique property of extraordinary optical transmission exhibited by the metal hole arrays 8 and 15, lasing signals are achieved at both the reflected and transmitted sides. This is in contrast to prior art lasers designed with an array of metal nanoparticles where the laser signal only appears at the reflected side. Therefore, the use of a metal hole array (such as arrays 100, 8, or 15) as the cavity allows for advanced control of laser performance.

By properly designing the period of the metal hole array, the spectral positions of SPP-Bloch waves or the Wood anomaly can be tuned, as can be inferred from Eqs. (1) and (2). The lasing frequency can be tuned by choosing optical gain media whose gain profile is matched with the frequency of the SPP-Bloch waves or Wood anomaly. The pumping angle (θ, see FIG. 2) should have no influence on the laser performance but should be aligned appropriately for the convenience of detecting laser signals. The pump light can be applied to either the top or the bottom side.

The material composition of the metal can be tuned to meet the requirements of designing lasers working at different frequencies. For the purpose of designing lasers in the visible wavelength region, the use of silver is preferable because it has the lowest losses. However, gold can also be used, although it does have higher losses than silver. An advantage of using gold is that it has better chemical resistance and higher environmental tolerance than silver. The selection of silver or gold depends on specific application requirements. For the purpose of designing lasers in the infrared wavelength region, the use of transparent conducting oxides, such as aluminum or gallium-doped zinc oxide, as the metal is preferable, since these materials have lower losses than silver in infrared wavelength regions.

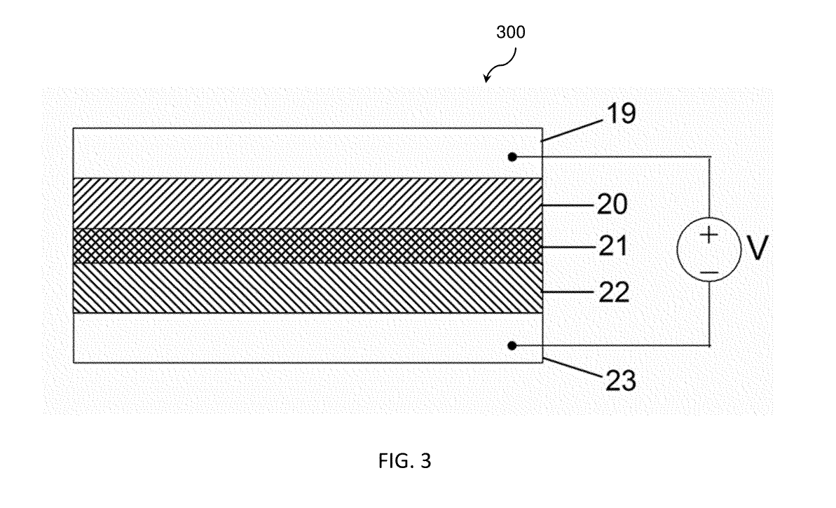

According to a further embodiment, a design of an electrically pumped laser device 300 is comprised of two metal films (19, 23) as electrodes, and semiconductors (20, 22) configured between them to provide optical gain, as shown in FIG. 3. At least one of the metal films 19, 23 is perforated with hole arrays, serving a dual purpose by acting as the electrode for facilitating the electrical pumping while also providing optical feedback for lasing. By way of an example, and not by way of limitation, the first semiconductor layer 20 is deposited between the metal film 19 and the gain medium 21, and comprising p-doped InP, for example. The second semiconductor layer 22 is deposited between the gain medium 21 and the metal film 23, and consists of n-doped InP, for example. The central frequency of the gain spectrum should be configured to approach the resonance wavelength of the SPP-Bloch wave described in Eq. (1) to achieve optimal optical feedback for lasing. For an example of operation wavelength at 1500 nm, the gain medium 21 is chosen to be InGaAs.

FIG. 4 illustrates a scanning electron microscope image of a hole array 400 perforated in a silver film 25. The hole array 400 is fabricated on a ITO-coated silica glass substrate. The X axis extends horizontally, and the Y axis extends vertically. The periods along X and Y axes are the same. The period, diameter, and the thickness of the holes 24 are 565 nm, 175 nm, and 100 nm, respectively.

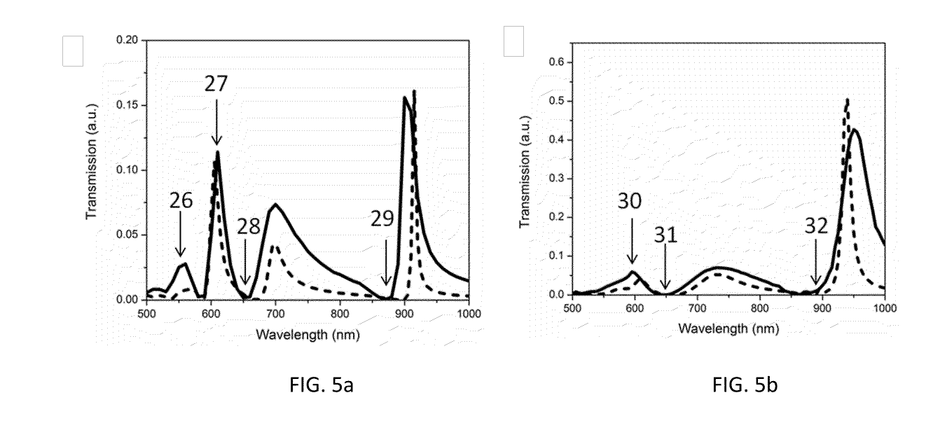

FIGS. 5a and 5b show the transmission spectra of the hole array 400 displayed in FIG. 4. More specifically, FIG. 5a illustrates the transmission spectrum of the hole array 400 with the period, diameter, and the thickness as 565 nm, 175 nm, and 100 nm respectively. The metal hole array of FIG. 5a is supported on an ITO-coated glass substrate and exposed to air. The alternating transmission maximum and minimum features correspond to the SPP-Block wave or Wood anomaly described in Eqs. (1) and (2). In FIG. 5a, the transmission spectrum is related to the SPP-Block wave or Wood anomaly on both of the metal-air and metal-silica interfaces. In detail, the transmission minima at 565 nm (denoted by reference 26), 650 nm (denoted by reference 28), and 885 nm (denoted by reference 29) can be correlated with the (1, 0)air, (1, 1)glass, and (1,0)glass SPP-Bloch waves described by Eq. (1). Herein, the subscript denotes the dielectric material at the interface with the metal. The integer index pairs indicate the orders of SPP-Bloch waves. The transmission maximum at λ=605 nm (denoted by reference 27) is related to (1, 1)glass Wood anomaly that is described by Eq. (2). In FIGS. 5a and 5b, the solid line shows the experimental data, the short dashed line shows the simulation results. The simulation is conducted using a finite element method in a commercial software package (Multiphysics, Comsol 4.3b).

In the case that the metal hole array 400 is covered by a layer of optical gain media, one must consider the resonances occurring on the two interfaces of metal-substrate and metal-gain. FIG. 5b gives an example (via transmission results) when the metal hole array is covered by a layer of polyvinyl alcohol (PVA) which is usually used as the host material for optical gain media comprising organic laser dyes. The transmission spectrum of the covered holes exhibits three major peaks centered at 600 nm (denoted by reference 30), 730 nm (denoted by reference 30), and 940 nm (denoted by reference 32), respectively. As expected, the transmission minima corresponding to the SPP-Bloch waves at the metal-glass interface appear at the same spectral positions with those in empty holes, and the resonances at metal-air interface vanish in the PVA-covered holes. Moreover, the spectral positions of SPP-Bloch waves and Wood anomalies at the metal-PVA interface resemble those at the metal-glass interface. This is understandable because the refractive index of PVA is rather close to that of the glass substrate.

For a more detailed example, illustrations have been disclosed herein regarding a specific design of a hole array, the optical properties that it exhibits, and how it is applied to initiate lasing actions (see FIGS. 4-6). As shown in FIG. 4, the hole array 400 has a regular period along the x- and y-axes, and the holes comprise circular shapes. In the case that the period is different in the x- and y-directions, additional coupled modes are expected to appear.

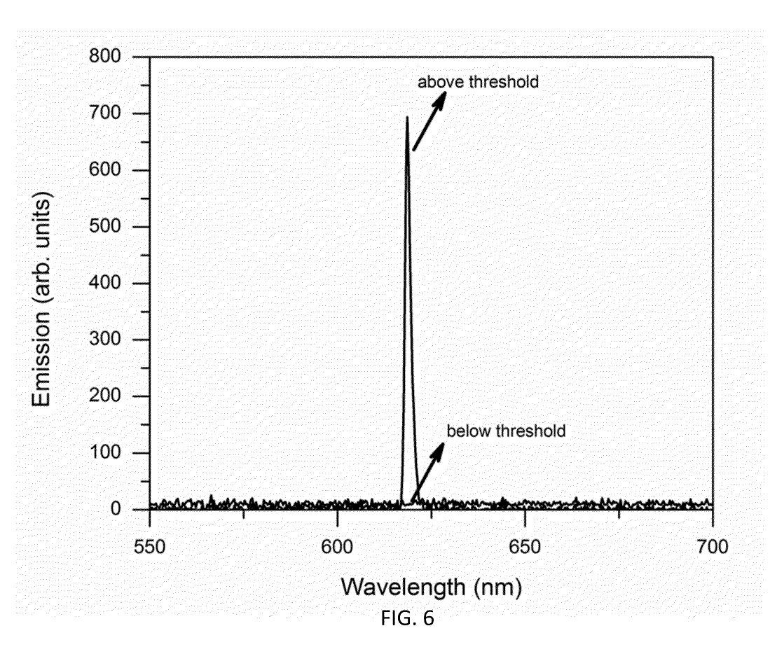

Referring to FIG. 6, also for example and disclosed herein is how laser actions are achieved using the metal hole array (i.e. the array design shown in FIG. 4) as the resonant cavity. The existence of SPP-Bloch waves indicates a strong SPP coupling, as well as a route to achieve lasing with a high efficiency and a low threshold. In one experimental example, amplification of the (1, 1)PVA SPP-Bloch mode located at 645 nm is attempted. For this purpose, an organic laser dye is chosen with a high quantum yield, Rhodamine 101 (R101), as the optical gain medium. R101 is an organic laser dye with the emission line centered at around 600 nm, which has been widely used to achieve laser devices in the red-wavelength region. The emission line is close to the resonance wavelength of the SPP-Bloch wave at 645 nm at (1, 1) silver-polymer interface, and thus an efficient energy transfer from R101 to the metal is expected to reach surface plasmon amplification. From FIG. 6, it is apparent that a laser line appears at around 620 nm when the pump energy is above the threshold, showing much more narrowed linewidth and intense signal when compared to the emission recorded below the pump threshold. The unique feature of this laser design is that both reflected and transmitted lasing signals are observed, which is apparently different from a laser designed with a metal nanoparticle array where only reflected lasing signal exists. In the example of FIG. 6, the concentration of R101 is 6×10¹⁸ cm⁻³ relative to the polymer host. The layer of optical gain medium is fabricated by spin-coating an aqueous solution containing PVA and R101. The thickness of the resultant optical gain layer is around 500 nm. The sample was optically pumped with a pulsed Neodymium-doped yttrium lithium fluoride (Nd: YLF) laser with operation wavelength at 527 nm, pulse width of 200 ns, and repetition rate of 1 Hz. The emission signal was collected with an optical fiber and analyzed in a monochromator system.

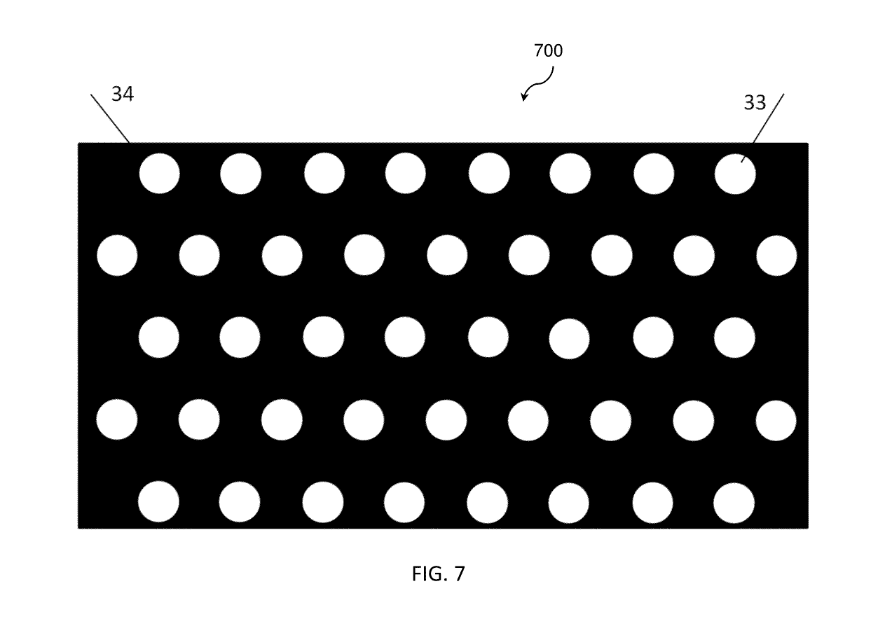

FIG. 7 illustrates an example of a hexagonal arrangement of a metal hole array 700. The holes 33 in the metal film 34 have uniform size and circular shape. Compared to square arrangement, as shown in FIG. 4, there is a strong anisotropy in the period of the holes along different directions. As indicated in Equations (1) and (2), this anisotropy can be used to realize advanced control of lasing properties such as polarization, resonant wavelength, emission direction, and pump threshold. The shapes of the holes can be changed to ellipsoids, rectangle, and the like.

The description of a preferred embodiment of the invention has been presented for purposes of illustration and description. It is not intended to be exhaustive or to limit the invention to the precise forms disclosed. Obviously, many modifications and variations will be apparent to practitioners skilled in this art. It is intended that the scope of the invention be defined by the following claims and their equivalents.

What is claimed is:

1. A laser made of a metallic cavity for control of a propagation direction of a laser emission, comprising:
an array of holes perforated in a planar metallic thin film, the film serving as a resonant cavity, and optically active media integrated in close vicinity to the resonant cavity to compensate for plasmonic losses, wherein coupling between plasmonic resonances, occurring in each individual hole of the array of holes, provides an optical feedback for light amplification, thus permitting lasing in optical frequencies.

2. The device of claim 1, wherein the metal comprises gold, silver, aluminum, copper, and transparent conducting oxides.

3. The device of claim 1, wherein the propagation direction of a laser emission is normal to the surface of the metal film.

4. The device of claim 1, wherein a signal propagates in both a reflected direction and a transmitted direction.

5. The device of claim 1, wherein the array of holes is arranged periodically and the spatial distribution of the array is square.

6. The device of claim 1, wherein the array of holes is arranged periodically and the spatial distribution of the array is hexagonal or rectangular.

7. The device of claim 1, wherein the shape of a hole is circular, elliptic, square or rectangular.

8. The device of claim 1, wherein the optical gain media is integrated above and below a hole.

9. The device of claim 1, wherein lasing occurs in the visible and infrared wavelength range.

10. The device of claim 1, wherein the optically active media comprises a dye or semiconductor.

11. The device of claim 10, wherein the dye is embedded in a host material to improve chemical stability and prevent fluorescence quenching.

12. The device of claim 11, wherein the host material comprises polymer, glass, and single crystal.

13. The device of claim 1, wherein the optically active media comprises at least one semiconductor comprising a thin film or a nanostructure.

14. The device of claim 1, wherein the optical gain media can be exposed to either optical or electrical pumping.

15. The device of claim 14, wherein the nanostructure further comprises various combinations of quantum dots and nanowires.

16. The device of claim 14, wherein the semiconductor/nanostructure is free standing.

17. The device of claim 14, wherein the semiconductor/nanostructure is embedded in a host material of polymer and glass.

18. The device of claim 1, wherein properties of the resonant cavity are tuned by adjusting a period, a diameter, and a thickness of the holes and the array of holes.

19. The device of claim 18, wherein the period primarily controls the resonant frequency of the resonant cavity.

20. The device of claim 18, wherein the diameter and the thickness control a linewidth of a resonant mode exhibited by the resonant cavity.
The device of claim 18, wherein a dimension of the diameter and thickness of a hole is on a sub-wavelength scale.
